(19) United States
(12) Patent Application Publication
(10) Pub. No.: US 2026/0330214 A1
(43) Pub. Date: Oct. 22, 2026

(54) Training Data Generation And Model Training Methods

(71) Applicant: Siemens Aktiengesellschaft, München (DE)

(72) Inventors: Feng Du, Shanghai (CN); Ling Bao Min, Shanghai (CN); Jian Qiang Wu, Shanghai (CN)

(73) Assignee: Siemens Aktiengesellschaft, München (DE)

(21) Appl. No.: 18/997,924

(22) PCT Filed: Jul. 25, 2022
(86) PCT No.: PCT/CN2022/107686

§ 371 Date: Jan. 23, 2025

(51) Int. Cl. G06N 3/08

(52) U.S. Cl. CPC G06N 3/08

(57) ABSTRACT

Various embodiments include a training data generation method comprising: in each opening/closing process in multiple openings/closings of a contact of a circuit breaker, obtaining time-series-based rotation angular displacement data of a main shaft of the breaker; converting the time-series-based rotation angular displacement data of the main shaft into time-series-based linear displacement data of the contact, to obtain first time series data; obtaining a control signal inside the breaker; converting the first time series data from an analog quantity to a digital quantity to obtain second time series data; performing filtering fusion processing on the second time series data using a preset filtering fusion algorithm to obtain third time series data; based on the control signal inside the breaker, calibrating the third time series data to obtain fourth time series data; and using a preset classification rule, respectively marking multiple groups of fourth time series data with corresponding category labels.

### CROSS-REFERENCE TO RELATED APPLICATIONS

This application is a U.S. National Stage Application of International Application No. PCT/CN2022/107686 filed Jul. 25, 2022, which designates the United States of America, the contents of which are hereby incorporated by reference in their entirety.

### TECHNICAL FIELD

Teachings of the present disclosure relate to artificial intelligence. Various embodiments of the teachings herein include methods and/or systems for training data generation and model training.

### BACKGROUND

A switch cabinet is an electrical device, which mainly functions to switch on/off, control, and protect electric devices in an electrical system for generating electricity, transmitting electricity, distributing electricity, and converting electrical energy. A medium voltage switch cabinet is a key component in the field of medium voltage electricity, and the state thereof is crucially important for the safety of a whole power station. If it is necessary to measure the state of a medium voltage switch cabinet, generally a stroke trajectory of a contact of a circuit breaker is measured online, then compared with a standard discrete feature value, and a measurement result is judged manually. However, with such a method, not only is it difficult to accurately measure the stroke trajectory of the contact, but also the judgment result obtained is strongly subjective.

### SUMMARY

Teachings of the present application include training data generation methods, model training methods, and electronic devices. High-quality data of the state of a circuit breaker in a medium voltage switch cabinet is generated to train a neural network model, and the trained neural network model can quickly and accurately predict the state of the circuit breaker.

For example, some embodiments include a training data generation method comprising: in each opening/closing process in multiple openings/closings of a contact of a circuit breaker, obtaining time-series-based rotation angular displacement data of a main shaft of the circuit breaker; converting the time-series-based rotation angular displacement data of the main shaft into time-series-based linear displacement data of the contact, to obtain first time series data; obtaining a control signal inside the circuit breaker; converting the first time series data from an analog quantity to a digital quantity, to obtain second time series data; performing filtering fusion processing on the second time series data using a preset filtering fusion algorithm, to obtain third time series data; according to the control signal inside the circuit breaker, calibrating the third time series data, to obtain fourth time series data; and, according to a preset classification rule, respectively marking multiple groups of fourth time series data with corresponding category labels.

As another example, some embodiments include a neural network model training method comprising: executing the training data generation method provided by the first aspect, to obtain a training dataset containing a preset quantity of training data; and using the training dataset to train a neural network model, to obtain an optimized neural network model, wherein the neural network model comprises: a CNN model or an LSTM model.

As another example, some embodiments include an electronic device comprising: at least one memory, which is configured to store a computer-readable code; and at least one processor, which is configured to call the computer-readable code, to execute one or more of the methods described herein.

As another example, some embodiments include a tangible computer-readable medium storing a computer-readable instruction, when executed by a processor, causes the processor to execute one or more of the methods described herein.

### BRIEF DESCRIPTION OF THE DRAWINGS

The accompanying drawings below are merely intended to illustrate and explain schematically the embodiments of the present application, without limiting the scope thereof. In the drawings:

FIG. 1 is a flowchart of an example training data generation method incorporating teachings of the present disclosure;

FIG. 2 is a schematic drawing of an example interior structure of a circuit breaker incorporating teachings of the present disclosure;

FIG. 3 is a flowchart of an example neural network model training method incorporating teachings of the present disclosure; and

FIG. 4 is a schematic drawing of an example electronic apparatus incorporating teachings of the present disclosure.

### KEY TO THE DRAWINGS

100: training data generation method
101-107: method step
20: circuit breaker
21: static contact
22: moving contact
23: main shaft
300: neural network model training method
301-302: method step
400: electronic device
401: processor
402: memory

### DETAILED DESCRIPTION

The subject matter described herein is now discussed with reference to exemplary embodiments. It should be understood that these embodiments are discussed purely in order to enable those skilled in the art to better understand and thus implement the subject matter described herein, without limiting the protection scope, applicability or examples expounded in the claims. The functions and arrangement of the elements discussed can be changed without departing from the protection scope of the content of the embodiments of the present dislocure. Various processes or components can be omitted from, replaced in or added to each example as required. For example, the method described may be performed in a different order from that described, and all of the steps may be added, omitted or combined. In addition, features described in relation to some examples may also be combined in other examples.

As used herein, the term “comprises” and variants thereof denote open terms, meaning “including but not limited to”. The term “based on” means “at least partly based on”. The terms “one embodiment” and “an embodiment” mean “at least one embodiment”. The term “another embodiment” means “at least one other embodiment”. The terms “first”, “second”, etc. may denote different or identical objects. Other definitions may be included below, either explicit or implicit. Unless clearly indicated in the context, the definition of a term is the same throughout the specification. Embodiments of the present application are explained in detail below with reference to the accompanying drawings.

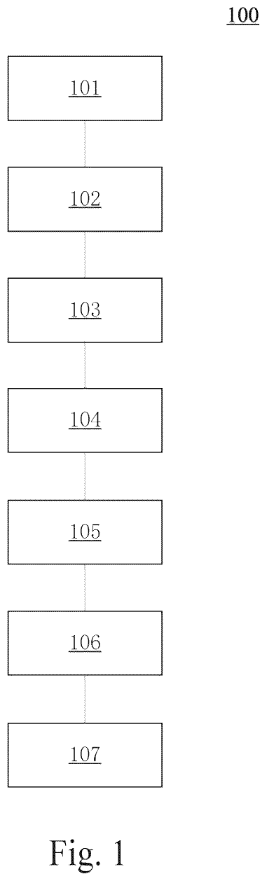

FIG. 1 shows a flowchart of an example training data generation method incorporating teachings of the present disclosure. As shown in FIG. 1, the training data generation method 100 comprises:

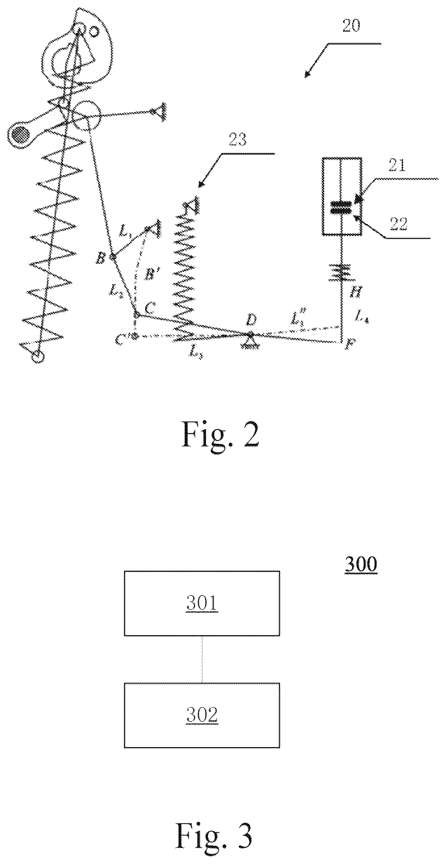

Step 101, in each opening/closing process in multiple openings/closings of a contact of a circuit breaker, obtaining time-series-based rotation angular displacement data of a main shaft of the circuit breaker. In some embodiments, time-series-based rotation angular displacement data of a main shaft 23 in a four-bar linkage formed by L₁, L₂, L₃ and L₄, as shown in FIG. 2, may be obtained by means of a rotary encoder.

Step 102, converting the time-series-based rotation angular displacement data of the main shaft into time-series-based linear displacement data of the contact, to obtain first time series data. By means of a calculation on a model of a four-bar linkage in the circuit breaker 20, a model proportionality constant k is obtained, and the time-series-based angular displacement data φ of the main shaft 23 is converted into time-series-based linear displacement data f of the contact, wherein

$$f = k * sin \frac{φ}{2} .$$

The contact is composed of a static contact 21 and a moving contact 22 in FIG. 2, wherein “static contact” refers to a contact that does not follow an action of execution mechanism, whereas the moving contact does follow the action of the execution mechanism.

In some embodiments, first time series data may be stored in an array form, or first time series data is stored in a curve form. The storage form determines the predictable data form of the final trained neural network model.

Step 103, obtaining a control signal inside the circuit breaker. The control signal inside the circuit breaker comprises: a current signal of a tripping and closing coil and a signal controlling opening and closing of the contact. The tripping and closing coil is a control element in a circuit control loop, and a tripping and closing coil current is specifically a coil current of an electromagnetic mechanism for driving tripping and closing actions of the circuit breaker.

Step 104, converting the first time series data from an analog quantity to a digital quantity, to obtain second time series data. Step 105, performing filtering fusion processing on the second time series data using a preset filtering fusion algorithm, to obtain third time series data. The preset filtering fusion algorithm may be: a Kalman filtering algorithm or a particle filtering algorithm. Using a relevant filtering fusion algorithm may reduce model estimation errors, such as errors of related parameters leading to errors of the function f, and related measurement errors.

Step 106, according to the control signal inside the circuit breaker, calibrating the third time series data, to obtain fourth time series data. The third time series data may be calibrated by means of the signal controlling opening and closing of the contact; specifically, at a moment when the signal controlling opening and closing of the contact is 0, the corresponding third time series data is cleared. The third time series data may also be calibrated by means of the tripping and closing coil current signal, for example deleting a relevant abnormal value, aligning the relevant time series data, etc.

Step 107, according to a preset classification rule, respectively marking multiple groups of fourth time series data with corresponding category labels. According to a preset classification rule, the multiple groups of fourth time series data are divided at least into two types. The first type of fourth time series data is marked with a first sample label; and the second type of fourth time series data is marked with a second sample label.

In some embodiments, a positive sample and a negative sample may be partitioned according to a preset number of disconnections; for example, data of the first 1000 trigger events acts as the positive sample and is marked with a “normal” label, then data of the latter 1000 trigger events acts as the negative sample and is marked with an “abnormal” label. In some embodiments, a relevant sample with an average moving speed, disconnection time or bounce interval that exceeds a preset range may act as a negative sample, and otherwise is a positive sample. In some embodiments, multiple groups of fourth time series data may be divided into multiple types according to an aging process; for example, data of the first 500 trigger events is marked with a 50% aging label, data of trigger events 500-1000 is marked with a 70% aging label, and data of trigger events 1000-1500 is marked with a 90% trigger label, etc.

Time-series-based rotation angular displacement data of a main shaft is converted into time-series-based linear displacement data of a contact, and then by means of relevant filtering fusion and relevant calibration, and further by marking relevant data with category labels, state data that is of high quality and closer to real values may be generated for training a neural network model.

FIG. 3 is a flowchart of an example neural network model training method incorporating teachings of the present application. As shown in FIG. 3, the neural network model training method 300 comprises:

Step 301, executing the training data generation method 100, to obtain a training dataset containing a preset quantity of training data.

Step 302, using the training dataset to train a neural network model, to obtain an optimized neural network model, wherein the neural network model comprises: a CNN model or an LSTM model. In some embodiments, time-series-based data of a contact in each opening/closing process of multiple openings/closings of a circuit breaker online is input to an optimized neural network model, and the optimized neural network model may be used for predicting a corresponding label, such as normal or abnormal.

The trained neural network models can quickly and accurately predict the state of a circuit breaker in a medium voltage switch cabinet, so as to intelligently monitor and protect the medium voltage switch cabinet.

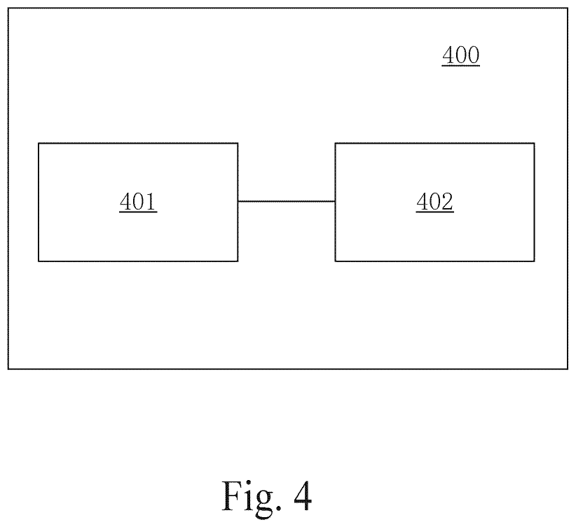

Teachings of the present disclosure include electronic devices. FIG. 4 is a schematic drawing of an example device control platform 400 incorporating teachings of the present disclosure. As shown in FIG. 4, the device control platform 400 comprises a processor 401 and a memory 402, an instruction being stored in the memory 402, wherein the instruction, when executed by the processor 401, implements one or more of the methods described above.

Processor 401 may comprise a microprocessor, an application specific integrated circuit (ASIC), a digital signal processor (DSP), a central processing unit (CPU), a graphics processing unit (GPU), a state machine, etc. Embodiments of computer-readable media include, but are not limited to, floppy disks, CD-ROM, magnetic disks, memory chips, ROM, RAM, ASIC, configured processors, all-optical media, all magnetic tapes or other magnetic media, or any other media from which instructions can be read by a computer processor. In addition, various other forms of computer-readable media may send or carry instructions to a computer, including a router, dedicated or public network, or other wired and wireless transmission devices or channels. The instructions may include code in any computer programming language, including C, C++, C language, Visual Basic, Java and JavaScript.

Some embodiments include a tangible computer-readable medium. A computer-readable instruction is stored on the tangible computer-readable medium, and the computer-readable instruction, when executed by a processor, causes the processor to perform one or more of the methods described above. Embodiments of computer-readable media include floppy disks, hard disks, magneto-optical disks, optical disks (such as CD-ROM, CD-R, CD-RW, DVD-ROM, DVD-RAM, DVD-RW, DVD+RW), magnetic tapes, non-volatile memory cards and ROM. In some embodiments, a computer-readable instruction may be downloaded from a server computer or a cloud through a communication network.

Not all of the steps and modules in the flows and system structure diagrams above are necessary; certain steps or modules may be omitted according to actual requirements. The sequence in which the steps are executed is not fixed and may be adjusted as needed. The system structures described in the embodiments above may be physical structures or logical structures, i.e., some modules might be realized by the same physical entity, or some modules might be realized by a plurality of physical entities or realized jointly by certain components in a plurality of independent devices.

What is claimed is:

1. A training data generation method comprising:
in each opening/closing process in multiple openings/closings of a contact of a circuit breaker, obtaining time-series-based rotation angular displacement data of a main shaft of the circuit breaker;
converting the time-series-based rotation angular displacement data of the main shaft into time-series-based linear displacement data of the contact, to obtain first time series data;
obtaining a control signal inside the circuit breaker;
converting the first time series data from an analog quantity to a digital quantity, to obtain second time series data;
performing filtering fusion processing on the second time series data using a preset filtering fusion algorithm to obtain third time series data;
based on the control signal inside the circuit breaker, calibrating the third time series data to obtain fourth time series data; and
using a preset classification rule, respectively marking multiple groups of fourth time series data with corresponding category labels.

2. The method as claimed in claim 1, wherein marking multiple groups of fourth time series data with corresponding category labels comprises:
according to a preset classification rule, dividing multiple groups of fourth time series data at least into two types;
marking the first type of fourth time series data with a first sample label; and
marking the second type of fourth time series data with a second sample label.

3. The method as claimed in claim 1, wherein obtaining a control signal inside the circuit breaker comprises:
obtaining a current signal of a tripping and closing coil; and
obtaining a signal controlling opening and closing of a contact.

4. The method as claimed in claim 1, herein the preset filtering fusion algorithm comprises: a Kalman filtering algorithm or a particle filtering algorithm.

5. The method as claimed in claim 1, wherein converting the time-series-based rotation angular displacement data of the main shaft into time-series-based linear displacement data of the contact comprises: using
a calculation on a four-bar linkage model in the circuit breaker, obtaining a model proportionality constant k, and converting the time-series-based angular displacement data φ of the main shaft into time-series-based linear displacement data f of the contact, wherein f=k*sin [symbol] [symbol] φ/2 [symbol] .

6. The method as claimed in claim 1, wherein obtaining first time series data comprises:
obtaining first time series data stored in an array form; or
obtaining first time series data stored in a curve form.

7. A neural network model training method comprising:
executing a training data generation method as claimed in claim 1 to obtain a training dataset containing a preset quantity of training data; and
using the training dataset to train a neural network model to obtain an optimized neural network model;
wherein the neural network model comprises: a CNN model or an LSTM model.

8. An electronic device comprising:
a processor; and
a memory storing a computer-readable instruction;
wherein the computer-readable instruction, when executed by the processor, causes the processor to:
in each opening/closing process in multiple openings/closings of a contact of a circuit breaker, obtain time-series-based rotation angular displacement data of a main shaft of the circuit breaker;
convert the time-series-based rotation angular displacement data of the main shaft into time-series-based linear displacement data of the contact, to obtain first time series data;
obtain a control signal inside the circuit breaker;
convert the first time series data from an analog quantity to a digital quantity to obtain second time series data;
perform filtering fusion processing on the second time series data using a preset filtering fusion algorithm to obtain third time series data;
based on the control signal inside the circuit breaker, calibrate the third time series data to obtain fourth time series data; and
using a preset classification rule; respectively mark multiple groups of fourth time series data with corresponding category labels.

9. (canceled)
